(19) United States
(12) Patent Application Publication
(10) Pub. No.: US 2026/0354220 A1
(43) Pub. Date: Nov. 5, 2026

(54) CHIPLET-TO-CHIPLET PROTOCOL SWITCH

(71) Applicant: ADEIA SEMICONDUCTOR BONDING TECHNOLOGIES INC., San Jose, CA (US)

(72) Inventors: Belgacem Haba, Saratoga, CA (US); Rajesh Katkar, Milpitas, CA (US); Abul Nuruzzaman, Saratoga, CA (US)

(21) Appl. No.: 19/737,379

(22) Filed: Jul. 10, 2026

Related U.S. Application Data
(63) Continuation of application No. 18/345,867, filed on Jun. 30, 2023, now Pat. No. 12,713,942.

(51) Int. Cl. H10W 70/60; H10W 74/00; H10W 90/00

(52) U.S. Cl. CPC H10W 70/60; H10W 70/611; H10W 90/00; H10W 74/00; H10W 90/794

(57) ABSTRACT

A bonded structure is disclosed. The bonded structure can include a carrier. The bonded structure can include a first die having a first communications circuitry to format a communication signal according to a first communication protocol and to transmit the communication signal. The bonded structure can also include a protocol switch die having circuitry to receive the communications signal and to convert the communication signal from the first communication protocol to a second communication protocol, wherein the second communication protocol is different from the first communication protocol. The protocol switch die can transmit the communication signal according to the second communication protocol. The bonded structure can also include a second die having a second communications circuitry to receive the communication signal formatted in the second communication protocol.

### RELATED APPLICATIONS

This application claims the benefit of U.S. Non-Provisional patent application Ser. No. 18/345,867, filed on Jun. 30, 2023, and entitled “CHIPLET-TO-CHIPLET PROTOCOL SWITCH,” which is incorporated by reference herein and made part of this specification.

### BACKGROUND

### Field

The field relates to a bonded structure with a chiplet-to-chiplet protocol switch die.

### Description of the Related Art

Semiconductor devices, in particular system on chip (SoC) devices, have increased in complexity while also decreased in size and dimension. As semiconductor devices become more complex, the importance of chiplet-to-chiplet communication of these devices has increased.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these implementations are intended to be within the scope of the invention herein disclosed. These and other implementations will become readily apparent to those skilled in the art from the following detailed description of the preferred implementations having reference to the attached figures, the invention not being limited to any particular preferred implementations disclosed.

In one implementations, a bonded structure can include: a carrier; a first die comprising a first communications circuitry to format a communication signal according to a first communication protocol and to transmit the communication signal, the first die directly bonded to the carrier without an intervening adhesive; a protocol switch die directly bonded to the carrier without an intervening adhesive, the protocol switch die comprising circuitry to receive the communications signal and to convert the communication signal from the first communication protocol to a second communication protocol, wherein the second communication protocol is different from the first communication protocol, wherein the protocol switch die transmits the communication signal according to the second communication protocol; and a second die comprising a second communications circuitry to receive the communication signal formatted in the second communication protocol, the second die directly bonded to the carrier without an intervening adhesive.

In some implementations, the protocol switch die converts the second communication protocol to the first communication protocol. In some implementations, the first communication circuitry receives the communication signal from the protocol switch die. In some implementations, the second communication circuitry transmits the communication signal. In some implementations, the protocol switch die includes processing circuitry to convert the first communication protocol to the second communication protocol. In some implementations, the processing circuitry converts the first communication protocol to a plurality of communication protocols. In some implementations, the processing circuitry converts the plurality of communication protocols to the first communication protocol. In some implementations, the processing circuitry converts the plurality of communication protocols to a second plurality of communication protocols. In some implementations, at least 90% of the circuitry is configured to convert between the communication protocols. In some implementations, the protocol switch die includes additional active circuitry configured for other processing functionalities.

In some implementations, the protocol switch die includes a memory to store various communication protocols. In some implementations, a format of the first communication protocol and a format of the second communication protocol is based on at least one of architecture, data rate, number of input/output interconnects, voltages, clock speed, power, latency, bit error rate, or channel loss. In some implementations, the architecture includes a serial architecture or a parallel architecture. In some implementations, the protocol switch die detects the format of the first communication signal and the format of the second communication signal. In some implementations, the protocol switch die detects the format of the first communication protocol and the format of the second communication protocol during an initial powering on state.

In some implementations, the carrier includes a semiconductor element or an interposer die. In some implementations, a first nonconductive bonding layer of the carrier is directly bonded to a second nonconductive layer of the first die without an intervening adhesive, and wherein a first contact feature of the carrier is directly bonded to a second contact feature of the first die without an intervening adhesive.

In some implementations, the first nonconductive bonding layer of the carrier is directly bonded to a third nonconductive layer of the second die without an intervening adhesive; and wherein the first contact feature of the carrier is directly bonded to a third contact feature of the second die without the intervening adhesive. In some implementations, the first nonconductive bonding layer of the carrier is directly bonded to a fourth nonconductive layer of the protocol switch die without an intervening adhesive; and wherein the first contact feature of the carrier is directly bonded to a fourth contact feature of the protocol switch die without an intervening adhesive.

In some implementations, the bonded structure includes one or more traces that electrically connect the first die and the second die to the protocol switch die. In some implementations, an encapsulating material is provided over a portion of the carrier, the first die, the second die, and the protocol switch die. In some implementations, the protocol switch die includes a multiplexer to receive at least one protocol of a plurality of incoming communication protocols and to convert the at least one protocol of the plurality of incoming communication to at least one protocol of a plurality of outgoing communication protocols based at least on a control input. In some implementations, the control input is based at least on a user input, an automatic determination, a present application, or a system application.

In another implementations, a bonded structure can include: a carrier comprising protocol switch circuitry to convert between a first communication protocol to a second communication protocol; a first die directly bonded to the carrier without an intervening adhesive, the first die comprising a first communication circuitry to format a communication signal according to the first communication protocol and to transmit the communication signal to the protocol switch circuitry; and a second die directly bonded to the carrier without an intervening adhesive, the second die comprising a second communication circuitry to receive the communication signal formatted according to the second communication protocol from the protocol switch circuitry, wherein the second communication protocol is different from the first communication protocol.

In some implementations, the protocol switch circuitry includes a processing circuitry to convert the first communication protocol to the second communication protocol. In some implementations, the protocol switch circuitry converts the first communication protocol to a plurality of communication protocols. In some implementations, the protocol switch circuitry converts the plurality of communication protocols to the first communication protocol. In some implementations, the protocol switch circuitry converts the plurality of communication protocols to a second plurality of communication protocols. In some implementations, the first communication circuitry receives the communication signal from the protocol switch circuitry. In some implementations, the second die transmits the communication signal. In some implementations, the protocol switch circuitry detects a format of the first communication protocol and a format of the another communication protocol. In some implementations, the protocol switch circuitry detects the format of the first communication protocol and the format of the second communication protocol during an initial powering on state.

In some implementations, a first nonconductive bonding layer of the carrier is directly bonded to a second nonconductive layer of the first die without an intervening adhesive and a first contact feature of the carrier is directly bonded to a second contact feature of the first die without an intervening adhesive. In some implementations, a first nonconductive bonding layer of the carrier is directly bonded to a third nonconductive layer of the second die without an intervening adhesive and a first contact feature of the carrier is directly bonded to a third contact feature of the second die without the intervening adhesive. In some implementations, the bonded structure includes one or more traces that electrically connect the first die and the second die to the protocol switch circuitry. In some implementations, an encapsulating material is provided over the carrier, the first die, and the second die. In some implementations, the protocol switch circuitry is embedded within the carrier. In some implementations, the protocol switch circuitry is patterned on the carrier.

In some implementations, the protocol switch die includes a multiplexer to receive at least one protocol of a plurality of incoming communication protocols and to convert the at least one protocol of the plurality of incoming communication protocols to at least one protocol of a plurality of outgoing communication protocols based at least on a control input. In some implementations, the control input is based at least on a user input, an automatic determination, a present application, or a system application.

In another implementations, a method of converting a first communication protocol to a second communication protocol can include: providing a first die comprising a first communications circuitry to format a communication signal according to the first communication protocol; providing a second die comprising a second communications circuitry to format the communication signal according to the second communication protocol; providing a protocol switch die to convert the first communication protocol to the second communication protocol; transmitting the communication signal formatted according to the first communication protocol from the first die to the protocol switch die; converting the communication signal from the first communication protocol to the second communication protocol at the protocol switch die; and transmitting the communication signal according to the second communication protocol from the protocol switch die to the second die, wherein the first die, the second die, and the protocol switch die are directly bonded to a surface of a carrier without an intervening adhesive such that the first die, the second die, and the protocol switch die are electrically connected.

In some implementations, the method includes converting the second communication protocol to the first communication protocol by the protocol switch die. In some implementations, the carrier includes an interposer die. In some implementations, the method includes detecting a format of the first communication protocol and a format of the second communication protocol by the protocol switch die. In some implementations, the method includes detecting the format of the first communication protocol and the format of the second communication protocol by the protocol switch die during an initial powering on state. In some implementations, the method includes electrically connecting the first die and the second die to the protocol switch die by one or more traces.

In another implementations, an integrated device die can include: an input terminal to receive a signal formatted in a first communication protocol; protocol switching circuitry to convert the signal from the first communication protocol to a second communication protocol; and an output terminal to transmit the signal formatted in the second communication protocol.

In some implementations, the integrated device die is directly bonded to an element without an intervening adhesive. In some implementations, the protocol switching circuitry processes switching between communication protocols and other processing functionalities different from switching between communications protocols. In some implementations, the integrated device die additional active circuitry for processing functionalities different from switching between communications protocols. In some implementations, the protocol switching circuitry converts the signal from the second communication protocol to the first communication protocol. In some implementations, the integrated device die includes processing circuitry to convert the first communication protocol to the second communication protocol. In some implementations, the processing circuitry converts the first communication protocol to a plurality of communication protocols. In some implementations, the processing circuitry convert the plurality of communication protocols to the first communication protocol. In some implementations, the processing circuitry converts the plurality of communication protocols to a second plurality of protocols.

In some implementations, the integrated device die includes a memory to store various communication protocols. In some implementations, a format of the first communication protocol and a format of the second communication protocol is based on at least one of architecture, data rate, number of input/output interconnects, voltages, clock speed, power, latency, bit error rate, or channel loss. In some implementations, the architecture includes a serial architecture or a parallel architecture. In some implementations, the integrated device die detects the format of the first communication signal and the format of the second communication signal. In some implementations, the integrated device die detects a format of the first communication protocol and the format of the second communication protocol during an initial powering on state. In some implementations, the integrated device die includes a multiplexer to receive at least one protocol of a plurality of incoming communication protocols and to convert the at least one protocol of the plurality of incoming communication protocols to at least one protocol of a plurality of outgoing communication protocols based at least on a control input. In some implementations, the control input is based at least on a user input, an automatic determination, a present application, or a system application.

In another implementation, a bonded structure can include: a carrier; a first die comprising a first communications circuitry to format a communication signal according to a first communication protocol and to transmit the communication signal; an integrated device die disposed in or on the carrier, the integrated device die comprising protocol switch circuitry to receive the communication signal and to convert the communication signal from the first communication protocol to a second communication protocol, wherein the second communication protocol is different from the first communication protocol, wherein the integrated device die transmits the communication signal according to the second communication protocol; and a second die comprising a second communications circuitry to receive the communication signal formatted in the second communication protocol.

In some implementations, the integrated device die converts the second communication protocol to the first communication protocol. In some implementations, the first communication circuitry receives the communication signal from the integrated device die. In some implementations, the second communication circuitry transmits the communication signal. In some implementations, the integrated device die includes processing circuitry to convert the first communication protocol to the second communication protocol. In some implementations, the processing circuitry converts the first communication protocol to a plurality of communication protocols. In some implementations, the processing circuitry converts the plurality of communication protocols to the first communication protocol. In some implementations, the processing circuitry converts the plurality of communication protocols to a second plurality of communication protocols.

In some implementations, the integrated device die includes a memory to store various communication protocols. In some implementations, a format of the first communication protocol and a format of the second communication protocol is based on at least one of architecture, data rate, number of input/output interconnects, voltages, clock speed, power, latency, bit error rate, or channel loss. In some implementations, the architecture includes a serial architecture or a parallel architecture. In some implementations, the integrated device die detects the format of the first communication signal and the format of the second communication signal. In some implementations, the integrated device die detects the format of the first communication protocol and the format of the second communication protocol during an initial powering on state, the carrier includes a semiconductor element or an interposer die.

In some implementations, the first die, second die, and integrated device die are direct bonded to the carrier. In some implementations, a first nonconductive bonding layer of the carrier is directly bonded to a second nonconductive layer of the first die without an intervening adhesive, and wherein a first contact feature of the carrier is directly bonded to a second contact feature of the first die without an intervening adhesive. In some implementations, the first nonconductive bonding layer of the carrier is directly bonded to a third nonconductive layer of the second die without an intervening adhesive, and wherein the first contact feature of the carrier is directly bonded to a third contact feature of the second die without an intervening adhesive. In some implementations, the first nonconductive bonding layer of the carrier is directly bonded to a fourth nonconductive layer of the integrated device die without an intervening adhesive, and wherein the first contact feature of the carrier is directly bonded to a fourth contact feature of the integrated device die without an intervening adhesive.

In some implementations, the first die, second die, and integrated device die are flip chip bonded to the carrier. In some implementations, the bonded structure includes one or more traces that electrically connect the first die and the second die to the integrated device die. In some implementations, an encapsulating material is provided over a portion of the carrier, the first die, the second die, and the integrated device die. In some implementations, the integrated device die includes a multiplexer to receive at least one protocol of a plurality of incoming communication protocols and to convert the at least one protocol of the plurality of incoming communication protocols to at least one protocol of a plurality of outgoing communication protocols based at least on a control input. In some implementations, the control input is based at least on a user input, an automatic determination, a present application, or a system application.

In another implementation, a method of manufacturing a bonded structure can include: providing a first die comprising a first communications circuitry to format a communication signal according to the first communication protocol; providing a second die comprising a second communications circuitry to format the communication signal according to the second communication protocol; providing a protocol switch die to convert the first communication protocol to the second communication protocol; directly bonding the first die, the second die, and the protocol switch to a surface of a carrier without an intervening adhesive such that the first die, the second die, and the protocol switch die are electrically connected; wherein the bonded structure transmits the communication signal formatted according to the first communication protocol from the first die to the protocol switch die; wherein the bonded structure converts the communication signal from the first communication protocol to the second communication protocol at the protocol switch die; and wherein the bonded structure transmits the communication signal according to the second communication protocol from the protocol switch die to the second die. In some implementations, in the carrier comprises an interposer die.

### BRIEF DESCRIPTION OF THE DRAWINGS

Various implementations will be described hereinafter with reference to the accompanying drawings. These implementations are illustrated and described by example only and are not intended to limit the scope of the disclosure. In the drawings, similar elements have similar reference numerals.

FIG. 1A is a schematic cross sectional side view of a bonded structure, according to various embodiments.

FIG. 1B is a schematic cross sectional side view of the bonded structure of FIG. 1A that includes an encapsulating material.

FIG. 2 illustrates the bonded structure of FIG. 1A or 1B.

FIG. 3A illustrates another implementation of a bonded structure that includes a protocol switch circuitry embedded on the carrier.

FIG. 3B illustrates another implementation of a bonded structure that includes a protocol switch circuitry patterned thereon.

FIG. 4 is a schematic cross-sectional side view of the bonded structure of FIG. 3A that includes an encapsulating material.

FIG. 5 illustrates the bonded structure of FIG. 2 connected to a carrier.

FIG. 6A is a schematic cross-sectional side view of two elements prior to direct hybrid bonding.

FIG. 6B is a schematic cross-sectional side view of a bonded structure including the two elements shown in FIG. 6A after direct hybrid bonding.

### DETAILED DESCRIPTION

The present disclosure may be understood by reference to the following detailed description. It is noted that, for purposes of illustrative clarity, certain elements in various drawings may not be drawn to scale, may be represented schematically or conceptually, or otherwise may not correspond exactly to certain physical configurations of embodiments.

Implementations relate to protocol switching elements for the conversion of protocol and/or communication signals between chiplets bonded (e.g., hybrid bonded, flip chip bonded, etc.) to a carrier (e.g. another chip, active or passive interposer, routing substrate, etc.). A bonded structure with a chiplet-to-chiplet protocol switch die and/or circuitry can be configured to convert one or more communication signals transmitted and/or received by to one or more adjacent chiplets that are in communication with one another. The protocol switch die can be programmed to convert signals conforming to a first protocol of a first chiplet to a second protocol of a second chiplet. Chiplet protocol conversion can refer to converting and/or translating data communication protocols between chiplets in a multi-chiplet system in which at least two chips operate or communicate according to different protocols. Chiplet protocol conversions can convert between different communication protocols of a chiplet manufacturer when chiplets use different communication protocols that are incompatible with each other. In a multi-chiplet system, different chiplets can have their own communication protocols based on their functionalities, design considerations, and/or legacy requirements. However, for effective communication and/or interoperability between chiplets, conversion between the communication protocol used by one chiplet into a format that can be understood by another chiplet in order for the chiplets to communicate with one another can take place in a separate die. Accordingly, there remains a continuing demand for improved communication translation and conversion devices and processes.

As applications and systems utilize more and more processing power, high performance chips (e.g., as CPUs (Central Processing Units), FPGAs (Field-Programmable Gate Arrays), APUs (Application Processor Units), ASICs (Application-Specific Integrated Circuits), ASSPs (Application-Specific Standard Parts), MCU (Microcontrollers), and/or GPUs (Graphics Processing Units)) including multi-core processors, and/or network switches) are becoming larger and larger. But the combination of reticle size challenges, optimized use of real estate using advanced node process, and/or yield of such large chips is driving the industry towards disaggregation and the adoption of chiplets. With advanced node semiconductor fabrication and evolving chip and system architectures, chip designers are adopting chip disaggregation by moving to multi-die architecture and the use advanced packaging to formulate advanced SoC designs. High-speed, high-performance chips need to communicate with each other, for example using high speed, high bandwidth communication. A die to interface, which is a functional block to provide interfacing data between dies within the same package can made of a physical layer (PHY) and/or controller blocks. The PHY can establish and maintain the physical transmission of data between network devices. The PHY can be implemented using high speed Serializer/Deserializer (SERDES) architecture or high-density parallel architecture. SERDES can convert parallel data into a serial data stream for transmission over a communication link and then converts it back to parallel data at the receiving end. The Serializer component of SERDES can take parallel data inputs and converts them into a serial bit stream by using techniques like encoding, modulation, and clock recovery. The Serializer can include features such as data serialization, parallel-to-serial conversion, and/or encoding schemes for error detection and correction. The Deserializer component, on the other hand, can receive the serial data stream and convert it back into parallel data. The Deserializer can perform tasks such as clock and data recovery, demodulation, and/or parallel-to-serial conversion. SERDES, as a functional block, can be part of a chiplet (e.g., a conversion process such as Parallel-In, Serial-Out (PISO), Serial-In, Parallel-Out (SIPO), etc.), but SERDES is designed to support a particular standard. In this instance, while SERDES is not extracted out of the chiplet and inputted into a conversion die, SERDES can be implement in several functional blocks on conversion dies to be able to communicate to SERDES on the chip. In some implementations, SERDES can be removed from the chiplet and placed on the conversion die, but some functionality may still remain on the chiplet to enable such off chiplet SERDES/parallel architecture. High speed chip-to-chip communication facilitated by SERDES, which can be one or more functional block on the chip that serializes and deserializes digital data. Complex SoCs implement SERDES to support multiple data rates and bandwidth with varied standards like UCIe, PCIe, MIPI, Ethernet, USB, SATA, etc. Although this communication interfacing could be broadly divided into such serial and parallel interfacing, the designers need to consider other parameters including overall bandwidth, beach front bandwidth (at the chip edges), latency, energy efficiency and power consumption, interconnect density, debug and repair strategy, etc. While these communication protocols are sometimes standardized, designing with same communication protocol standard for all the chips with varied the functionalities, process nodes, applications, and/or supply chains, can be challenging (e.g. one manufacturing partner may have its own proprietary communication protocol that they may not want to design away from it). High-density parallel architecture can refer to maximizing the number of computing elements and/or processing units within a given physical space and/or form factor. Parallel architecture can achieve high computational power and/or performance by leveraging a large number of parallel processing units. In high-density parallel architecture, multiple processing units, such as CPUs, FPGAs, APUs, ASICs, ASSPs, MCUs, and/or GPUs, can be densely packed together to form a parallel computing system. These processing units can work together simultaneously, independently, and/or in a coordinated manner to perform complex computations and process large amounts of data in parallel.

To facilitate such complicated inter-chiplet interfacing, chiplet protocol conversion can include one or more components that act as protocol converters and/or adapters. These components receive data in one protocol format, perform the conversions and/or translations, and output the data in the desired protocol format. The conversion can include modifying data structures, adapting communication speeds, bandwidth adjustments and latency, interconnect density at the beach front, adjusting voltage levels, and/or translating control signals, clock or clock forwarding, number of channels, error detection and debug protocols, repair strategy, physical layer linking and die to die adaptor along with modifications based on packaging of choice (e.g. organic or Si interposer, reconstituted die/wafer, organic or Silicon bridge, high density routing (e.g. RDL)), etc. Chiplet protocol conversion can occur using hardware-based solutions, such as specialized protocol conversion chips and/or integrated circuits (ICs), or through software-based solutions implemented in microcontrollers and/or programmable devices as well as combination of such hardware and software solutions. The conversion choice can depend on the complexity of the protocol conversion, the performance requirements, and/or the available resources in the system. Chiplet protocol conversion can enable communication and/or data exchange between chiplets that would otherwise be incompatible due to different communication protocols. Further, chiplet protocol conversion can play a role in multi-chiplet systems, allowing diverse chiplets to work together effectively and/or facilitate the overall functionality and performance of the system.

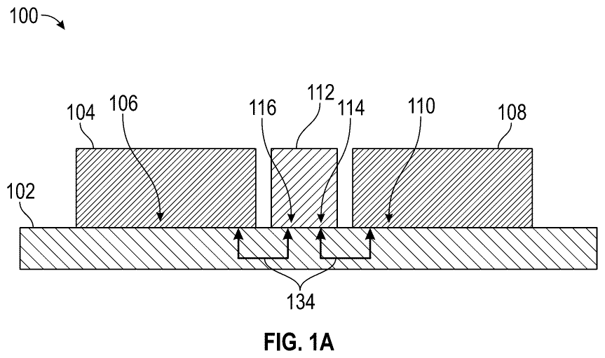

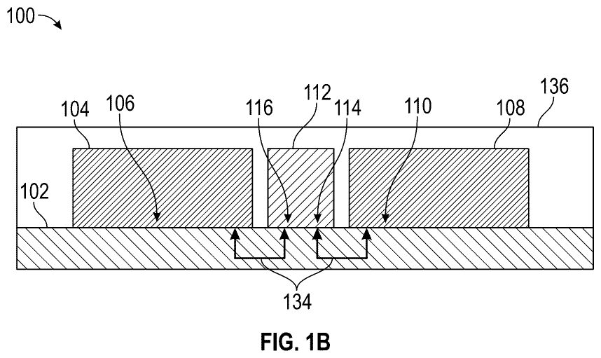

FIG. 1A is a schematic side sectional view of a bonded structure 100 including a carrier 102, a first die 104 having a first communication circuitry 106 to format a communication signal for transmission according to a first communication protocol, a second die 108 having a second communication circuitry 110 to receive the communication signal formatted in a second communication protocol, and a protocol switch die 112 having processing circuitry 114 to receive the communication signal from the first die 104 and convert the communication signal from the first communication protocol to the second communication protocol before transmitting the communication signal to the second die 108. In some implementations, the first die 104, second die 108, and/or the protocol switch die 112 can be integrated device dies. Additionally or alternatively, the protocol switch die 112 can receive the communication signal from the second die 108 and convert the communication signal from the second communication protocol to the first communication protocol before transmitting the communication signal to the first die 104, so as to enable a two-way interaction between first die 104 and second die 108. In some implementations, the protocol switch die 112 can be an integrated device die having protocol switch circuitry. For example, the integrated device die can include protocol switch circuitry 212 described below.

The first communication circuitry 106, second communication circuitry 110, and/or processing circuitry 114 can be located near and/or adjacent a surface of their respective die closest to the carrier 102. In other implementations, the first communication circuitry 106, second communication circuitry 110, and/or processing circuitry 114 can be located at the front or back of their respective dies (e.g., near and/or adjacent to an upper or lower surface relative to the carrier 102). The first die 104, second die 108, and/or protocol switch die 112 can be in a front-to-front bonding configuration with the carrier 102 (e.g., aligned and bonded together at their front surfaces where the active electronic devices and/or circuitry are located) and/or in a back-to-back bonding configuration with the carrier 102 (e.g., aligned and bonded together at their back surfaces) and/or in a front-to-back bonding configuration with the carrier 102. If the backside of any of the dies 104, 108, 112 are attached to the carrier 102, through-substrate vias (TSVs) can electrically connect the circuitry on the front top of the carrier 102 to contacts disposed on the bottom and/or back of the dies 104, 108, 112. The first communication protocol and the second communication protocol can include one or more different characteristics that are incompatible with one another as explained herein. The protocol switch die 112 can switch between any number of formats and can detect which of a plurality of conversions to make as further described below.

The first die 104 and/or second die 108 can by any suitable type of die and/or chiplet. For example, the first die 104 and/or second die 108 can be processor chiplets (e.g. compute, accelerator, etc.), memory chiplets, graphic chiplets, controller chiplets, IO chiplets, analog, RF and/or optical chiplets, specialized chiplets, etc. The first die 104 and/or second die 108 can be fabricated by any fabrication process node. For example, first die 104 may be fabricated using first fabrication process node (e.g. 5 nm) and second die 108 may be fabricated using second process node (e.g. 22 nm). The first die 104 and/or second die 108 can perform the same or different types of functions with active circuitry configured for those functions. The specific types and/or functionalities of the first die 104 and/or second die 108 can vary depending on the intended application and/or system requirements. The first communication circuitry 106 of first die 104 and the second communication circuitry 110 of second die 108 can comprise a portion of the active circuitry (or can be separate from the active circuity) that performs the primary function of the first die 104 and second die 108. The first communication circuitry 106 and second communication circuitry 110 can transmit outputs from and/or receive inputs to their respective dies which are used by the active circuitry to perform their respective functionalities.

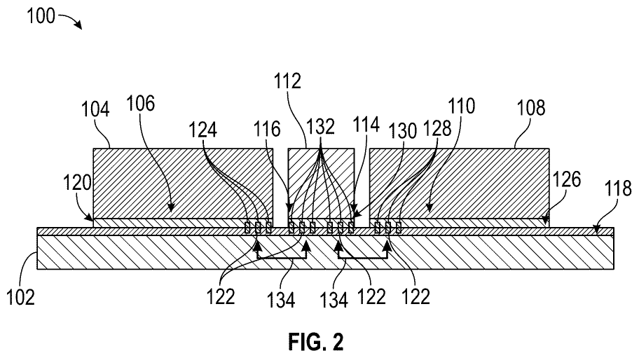

In some implementations, as shown in FIG. 2, the first die 104, second die 108, and protocol switch die 112 can be bonded adjacent to one another on the carrier 102. The first die 104, second die 108, and/or protocol switch die 112 can be directly bonded to (e.g., hybrid bonded to) the carrier 102 without an intervening adhesive. In some implementations, the carrier 102 can include a semiconductor element (e.g., an active device die or chip with active circuitry, an interposer die and/or a reconstituted wafer/die. In another implementation, the first die 104, second die 108, and/or protocol switch die 112 can be bonded using other methods (e.g. flip chip bonding).

Communication protocols can be the language and/or formats by which two or more chiplets communicate to one another within a system or package. The communication protocol is a set of rules and/or conventions that can define how information is exchanged and transmitted between two or more chiplets. The choice of communication protocol for chiplets can depend on one or more factors such as system requirements, performance needs, power constraints, and/or compatibility with existing infrastructure. Different chiplets within a system can use different protocols depending on their specific functionalities and/or communication requirements. In some implementation, the protocol switch die 112 can convert the second communication protocol to the first communication protocol. The second communication circuitry 110 can transmits the communication signal from the second die 108 to the protocol switch die 112. The first communication circuitry 106 can receive the communication signal from the protocol switch die 112.

In some implementations, the bonded structure 100 can also include one or more traces along a communication path 134 that electrically connect the first die 104 and the second die 108 to the protocol switch die 112. The traces can be embedded in one or more interconnect layers formed in or on carrier 102. In some implementations, as illustrated in FIG. 1B, an encapsulating material 136 can be provided over a portion of the carrier 102, the first die 104, the second die 108, and the protocol switch die 112. The encapsulating material 136 can include one or multiple layers. In some implementations, the encapsulating material 136 can be an inorganic dielectric (e.g., silicon oxide, silicon nitride). In other implementations, the encapsulating material 136 can be an organic dielectric, such as a epoxy molding compound (EMC) or combination of organic or inorganic materials. The encapsulating material 136 can serves to protect the first die 104, second die 108, and/or protocol switch die 112.

The communication circuitry of the dies and/or chiplets mentioned herein can format the communication signals to be transmitted and/or received by other dies and/or chiplets. A format of the first communication protocol (in some implementations the source signal) and/or the second communication protocol (in some implementations the destination signal) can be based on at least one of architecture, power, latency, data rate, number of input/output interconnects, voltages, clock speed, bit error rate, and/or channel loss. In some implementations, the format of the architecture can include parallel architecture and/or serial architecture. In some implementations, the architecture can include SERDES architecture or high-density parallel architecture as described above. In a parallel architecture, multiple dies are connected to one another using multiple communication channels. Data is then transferred in parallel through the multiple communication channels. By using multiple channels in parallel, there is a high bandwidth, low data rate exchange per lane, low latency, and lower power requirements as well as high cross coupling noise, high capacitive load, and high leakage power. An interposer (or a reconstituted die/wafer component) can provide the pin connections for high-density routing. In contrast, for a series architecture, dies can be connected sequentially resulting in fewer interconnect structures being used. The serial interconnect interfaces include a limited bit rate, high latency, and higher power, which can be accomplished over low-density routing. Choosing between a parallel or a series configuration can depend on data transfer rates, power constraints, package size, etc. In a parallel configuration, each die and/or chiplet can have its own communication protocol implementation and communication channels with additional communication conversion components between each die. In a series configuration, communication conversion components can convert the communication signal as each stage of the of the signal transmission, which can reduce power consumption.

Different communication protocols can additionally or alternatively use various voltage levels to represent logic states, which can be converted between the various communication protocols. The communication conversion components (e.g., protocol switch die 112) can receive the voltage of the transmitted signal and match the voltage requirement of the receiving chiplet. If the voltage levels differ, voltage level shifting or voltage level conversion techniques can be employed to match the requirements of the receiving chiplet. The protocol conversion process can involve translating the voltage levels of the signals from the source protocol to the voltage levels expected by the destination protocol. This translation can ensure that the converted signals adhere to the voltage specifications of the receiving chiplet and can be reliably interpreted.

A communication protocol conversion can additionally or alternatively vary clocking mechanisms and/or speeds. Clock frequency of protocols determines the rate of which data is transmitted and received. Communication protocols can have synchronous (e.g., uses a clock signal to synchronize data transmission, with data being sent in predefined frames or packets) or asynchronous (e.g., do not use a clock signal and instead rely on start and stop bits or other synchronization methods) timing. A difference in clocking mechanisms and/or speeds can be aligned during a conversion. Frequency format, such as bit rate, can additionally or alternatively be considered for any conversions to take place as the frequency of the clock signal can impact the bit rate of the protocol. Higher clock frequencies can allow for faster data transfer rates, while lower frequencies result in slower data rates. When converting between protocols, the difference in clock frequencies may affect the achievable bit rate of the converted protocol. The data transfer rate and timing characteristics, including data setup/hold times, clock frequency, and data valid windows, should be converted to maintain data integrity and meet timing constraints.

Communication protocol conversions can additionally or alternatively consider error detection and handling considerations. These mechanisms for error detection, such as checksums or CRC (Cyclic Redundancy Check), which is an error-detecting code commonly used in digital networks and storage devices to detect accidental changes to digital data, can be preserved during the protocol conversion. Similarly, bit error rate (BER), which is a measure of the number of erroneous bits in a data transmission system relative to the total number of transmitted bits can be considered in protocol translations. When converting protocols between chiplets, the BER can provide an indication of the quality and reliability of the converted signal. The source and destination protocols can have specific BER requirements and/or specifications that need to be met for reliable data transmission. These specifications define the acceptable level of error rate for the system to operate effectively. The protocol conversion process should aim to maintain or improve the BER performance within the specified limits.

Channel loss can refer to the attenuation and/or degradation of a signal as it travels through a communication channel. During conversion, the converted signal can additionally or alternatively take into account the effects of the channel loss to maintain reliable communication between the chiplets. Channel loss can result in a reduction of signal amplitude and quality. As the signal passes through the channel, it may experience attenuation, distortion, and/or noise. These effects can impact the accuracy and reliability of the data being transmitted. When converting protocols, the conversion process can consider the signal integrity requirements of both the source and destination protocols such that the converted signal maintains an acceptable level of integrity. In some cases, the protocol conversion process can adapt the converted signal to better suit the characteristics of the communication channel. This adaptation can include modifying the signal encoding, adjusting voltage levels, and/or implementing other signal processing techniques to enhance compatibility and minimize the impact of channel loss.

Accordingly, various implementations disclosed herein can utilize a protocol switch die and/or circuitry to convert between two or more communication protocols with varying data and/or signal formats as explained above. The protocol switch die and/or circuitry can detect which of a plurality of conversions to make. By translating communication protocols between or more dies, chiplet from different manufacturers and/or differing communication protocols can be integrated into one system. For example, the protocol switch die 112 can detect the format of the first communication signal and/or a format of the second communication signal at any suitable time. For example, the protocol switch die 112 can detect a format of the format of the first communication protocol and/or the format of the second communication protocol during an initial powering on state. In other implementations, the protocol switch die 112 can detect the format of the first and/or second communication protocol upon receiving the first and/or second communication protocol. In some implementations, a user, such as a manufacturer and//or operator, can pre-select the format of the first and/or second communication protocol. The protocol switch die 112 can also be pre-set to the formats of the first and/or second communication protocol.

The protocol switch die 112 can also include processing circuitry 114 to convert the first communication protocol to the second communication protocol. In some implementations, the processing circuitry 114 can convert the first communication protocol to a plurality of communication protocols. Additionally or alternatively, the processing circuitry 114 can convert the plurality of communication protocols to the first communication protocol. In some implementations, the processing circuitry 114 can convert the plurality of communication protocols to a second plurality of communication protocols. In some implementations, the protocol switch die 112 can include circuity (e.g., processing circuitry 114) to convert between the communication protocols. Additionally or alternatively, at least 90% of the circuitry can be allocated to convert between the communication protocols. In some implementations, the protocol switch die 112 can include additional active circuitry for other processing functionalities alongside the circuitry for converting the communication protocols. The protocol switch die 112 can include a memory 116 to store various communication protocols such as the first communication protocol, the second communication protocol, the first plurality of communication protocols, and/or the second plurality of communication protocols. In some implementations, by including various communication protocols within the memory 116, the protocol switch die 112 can be enabled to select the appropriate communication protocol conversion to make. In some implementations, the protocol switch die 112 can comprise circuitry including a multiplexer that can receive any one of several incoming communication protocols (e.g., the first communication and/or the plurality of communication protocols) and convert the any one of several incoming communication protocols to any one of several outgoing communication protocols (e.g., the second communication protocol and/or the plurality of communication protocols) based at least on a control input such as a user input, an automatic determination, a present application, and/or a system application. Additionally or alternatively, the multiplexer can receive any one of several incoming communication protocols and convert the any one of several incoming communication protocols to a singular outgoing communication protocols based at least on a user input and/or a system application. The multiplexer can select between one or more incoming signals and route the one or more incoming signals to a single output. As mentioned above, the multiplexer can allow for data and/or signals from different sources to be combined and/or selected based on the control inputs. The control inputs can be based on a user input, an automatic determination, a present application, and/or a system application.

FIG. 2 illustrates the bonded structure of FIG. 1A or FIG. 1B showing the first die 104, second die 108, and protocol switch die 112 directly bonded to the carrier 102. In some implementations, direct bonding can be direct hybrid bonding as described below. In some implementations, one or more of first die 104, second die 108, and/or protocol switch die 112 can be flip chip bonded to the carrier 102. As illustrated in FIG. 2, in some implementation, the carrier 102 can include a first nonconductive (e.g., an inorganic dielectric) bonding layer 118. In some embodiments, the first nonconductive bonding layer 118 can include silicon oxide, silicon nitride, silicon oxynitride, silicon oxycarbonitride, or silicon carbonitride. The first nonconductive bonding layer 118 of the carrier 102 can be directly bonded to a second nonconductive layer 120 of the first die 104 without an intervening adhesive. A first contact feature 122 (e.g., contact pads, exposed ends of vias (e.g., TSVs), or a through substrate electrodes) of the carrier 102 can be directly bonded to a second contact feature 124 of the first die 104 without an intervening adhesive. In some implementations, the first nonconductive bonding layer 118 of the carrier 102 can be directly bonded to a third nonconductive layer 126 of the second die 108 without an intervening adhesive. The first contact feature 122 of the carrier 102 can be directly bonded to a third contact feature 128 of the second die 108 without an intervening adhesive. Further, in some implementations, the first nonconductive bonding layer 118 of the carrier 102 can be directly bonded to a fourth nonconductive layer 130 of the protocol switch die 112 without an intervening adhesive. The first contact feature 122 of the carrier 102 can be directly bonded to a fourth contact feature 132 of the protocol switch die 112 without an intervening adhesive. The first contact feature 122, second contact feature 124, third contact feature 128, fourth contact feature 132 can provide electrical communication to the other elements. Additionally, or alternatively, the first contact feature 122, second contact feature 124, third contact feature 128, fourth contact feature 132 can include discrete conductive pads. In some implementations, the protocol switch die 112 can be in electrical communication with two or more dies and/or chiplets. The protocol switch die 112 can perform more than one communication protocol conversion between the varies dies and/or chiplets. Although the contact features 122, 124, 128, and 132 can provide electrical communication link between these elements are shown, other contacts that help directly communicate the first die 104, second die 108, and/or protocol switch die 112 with the carrier 102 without communicating to other die may also be available.

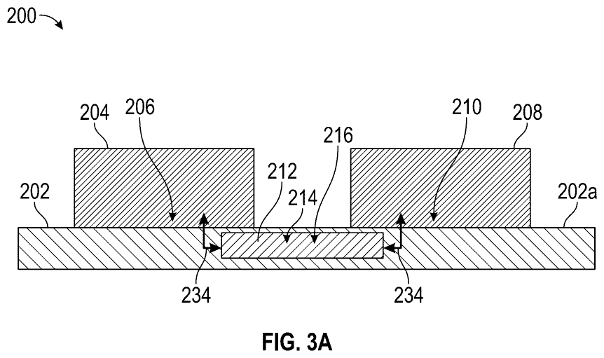

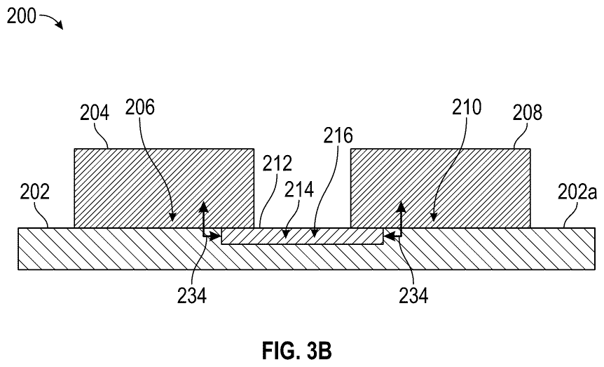

FIGS. 3A and 3B illustrate another implementation of a bonded structure 200. FIGS. 3A and 3B are generally similar to the implementations of FIGS. 1A-2. Unless noted otherwise, the components in FIGS. 3A and 3B may be the same as or generally similar to the like-numbered components of FIGS. 1A-2. As illustrated in FIGS. 3A and 3B, the bonded structure 200 can include a carrier 202 having protocol switch circuitry 212 to convert a first communication protocol to second communication protocol (i.e., the first communication protocol is different than the second communication protocol), a first die 204 having a first communication circuitry 206 to format a communication signal according to a first communication protocol and to transmit the communication signal to the protocol switch circuitry 212, and second die 208 having a second communication circuitry 210 to receive the communication signal formatted according to the second communication protocol from the protocol switch circuitry 212.

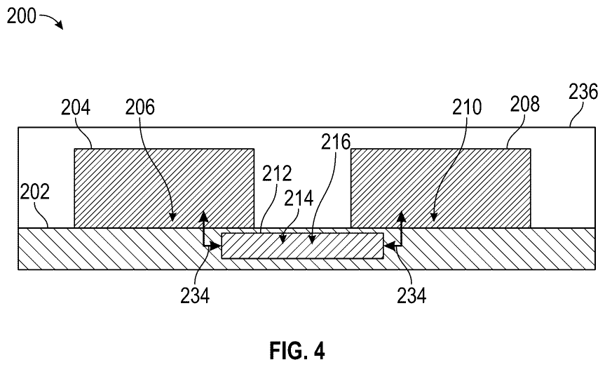

The protocol switch circuitry 212 can be embedded within an insulating layer of the carrier 202 (e.g., a substrate such as a printed circuit board (PCB), interposer and/or reconstituted component) as shown in FIG. 3A. For example, in FIG. 3A, the protocol switch circuitry 212 can comprise a chip or discrete device (e.g., bridge die) that is embedded in insulating layers of the carrier 202 (which can be a package substrate or other substrate). As shown in the embodiment of FIG. 3B, the carrier 202 can be a semiconductor element (e.g., a die) in which the protocol switch circuitry 212 can be patterned or formed in the carrier 202. The first communication circuitry 206, second communication circuitry 210, and/or processing circuitry 214 can be located near and/or adjacent a surface of their respective die closest to a first surface 202a of the carrier 202. In other implementations, the first communication circuitry 206, second communication circuitry 210, and/or processing circuitry 214 can be located anywhere within their respective dies (e.g., near and/or adjacent to an upper or lower surface relative to the first surface 202a of the carrier 202). In some implementations, as illustrated in FIG. 4, an encapsulating material 236 can be provided over a portion of the carrier 202, the first die 204, and/or the second die 208. The encapsulating material 236 can include one or multiple layers. In some implementations, the encapsulating material 236 can be an inorganic dielectric (e.g., silicon oxide, silicon nitride). In other implementations, the encapsulating material 236 can be an organic dielectric, such as a polymer (e.g., epoxy, epoxy molding compound, etc.). The encapsulating material 236 can serves to protect the first die 204, and/or the second die 208.

In some implementations, the first die 204 and/or second die 208 can include any number of dies (e.g., 1, 2, 3, 4, 5, 6, 7, 8, 9, 10, or more dies). The first die 204 and/or the second die 208 can be directly bonded without an intervening adhesive to the carrier 202. In some implementations, the protocol switch circuitry 212 can convert second communication protocol to the first communication protocol. The first communication circuitry 206 can receive the communication signal from the protocol switch circuitry 212. The second die 208 can transmit the communication signal to the protocol switch circuitry 212. In some implementations, the bonded structure can also include one or more traces 234 that electrically connect the first die 204 and the second die 208 to the protocol switch circuitry 212.

The protocol switch circuitry 212 can include the processing circuitry 214 to convert the first communication protocol to the second communication protocol. The processing circuitry 214 can be adjacent the first surface 202a of the carrier 202 or anywhere within the die containing the protocol switch circuitry 212. The protocol switch circuitry 212 can also convert the first communication protocol to a plurality of communication protocols. Additionally or alternatively, the protocol switch circuitry 212 can convert the plurality of communication protocols to the first communication protocol. In some implementations, the protocol switch circuitry 212 can convert the plurality of communication protocols to a second plurality of communication protocols.

The protocol switch circuitry 212 can also include memory circuitry 216 to store various communication protocols such as the first communication protocol, the second communication protocol, the first plurality of communication protocols, and/or the second plurality of communication protocols. The memory circuitry 216 can be adjacent the first surface 202a of the carrier 202 or anywhere within the die of FIG. 3A and/or substrate of FIG. 3B containing the protocol switch circuitry 212. A format of the first communication protocol and/or the second communication protocol can be based on at least one of architecture, data rate, number of input/output interconnects, voltages, clock speed, power, latency, bit error rate, or channel loss. In some implementations, the architecture can include serial architecture and/or parallel architecture. The protocol switch circuitry 212 detects the format of the first communication signal and/or a format of the second communication signal at different times. For example, the protocol switch circuitry 212 can detect a format of the format of the first communication protocol and/or the format of the second communication protocol during an initial powering on state. In other implementations, the protocol switch circuitry 212 can detect the format of the first and/or second communication protocol upon receiving the first and/or second communication protocol.

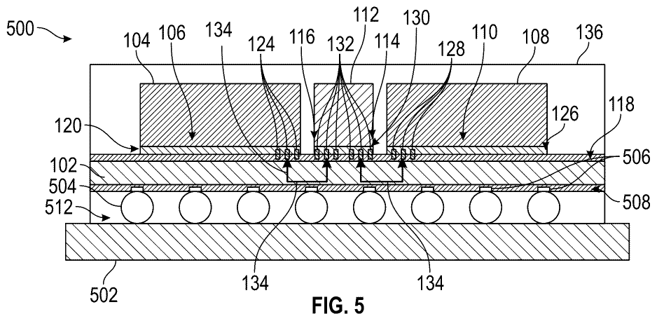

FIG. 5 illustrates the bonded structure 100 of FIG. 2 in bonded to a second carrier 502, but any of the bonded structures mentioned herein can be bonded to the second carrier 502. Unless otherwise noted, the components in FIG. 5 may be the same as or generally similar to like-numbered components of FIG. 2. As shown in FIG. 5, the bonded structure 100, including the carrier 102, first die 104, second die 108, and protocol switch die 112, can be further electrically and mechanically connected to the second carrier 502 to form a package assembly 500. In some implementations, the carrier 102, first die 104, second die 108, and protocol switch die 112 can be connected to the second carrier 502 by way of a plurality of solder balls 504 or other conductive adhesive. In other implementations (e.g., implementations in which the external device comprises another die, interposer, or wafer), the bonded structure 100 of FIG. 2 can be directly bonded to an external device. The carrier 102 can have corresponding conductive contact pads 506 to provide an electrical connection to another element. The contact pads 506 can include discrete conductive pads disposed in a respective nonconductive field region 508 (e.g., a nonconductive bonding layer). Once connected, an underfill material 512 can be applied around the solder balls 504. The underfill material 512 can include an insulating material that isolates the solder balls 504 from one another and connects the second carrier 502 to the bonded structure 100.

In some implementations, the second carrier 502 can further comprise conductive bumps or solder balls 504 to connect the second carrier 502 to an external device (such as a system board or other device). In some implementations, the carrier 102, first die 104, second die 108, and protocol switch die 112 can be at least partially encapsulated in an encapsulating material 136, which include an organic dielectric (e.g., a polymer such as a molding compound), or an inorganic dielectric (such as silicon oxide, etc.).

Various implementations disclosed herein relate to directly bonded structures in which two or more elements can be directly bonded to one another without an intervening adhesive. In some embodiments, direct bonding can involve bonding of a single material on one element and a single material on the other element, where the single materials on the different elements may or may not be the same. Direct bonding can also involve bonding of multiple materials on one element to multiple materials on the other element (e.g., hybrid bonding).

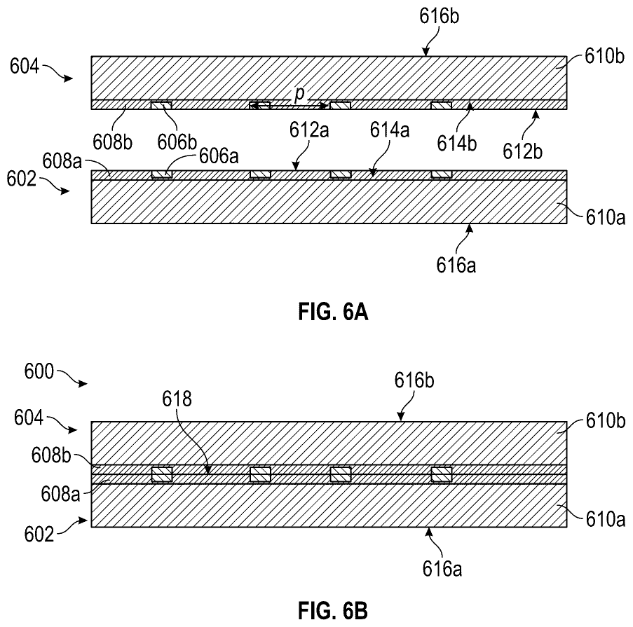

FIGS. 6A and 6B schematically illustrate a process for forming a hybrid bonded structure without an intervening adhesive (which may sometimes be referred to as a “direct hybrid bonded structure”) according to some implementations. As used herein, the term “hybrid bonding” refers to a species of direct bonding in which there are both i) nonconductive features directly bonded to nonconductive features, and ii) conductive features directly bonded to conductive features. In FIGS. 6A and 6B, a bonded structure 600 comprises two elements 602 and 604 that can be directly bonded to one another at a bond interface 618 without an intervening adhesive. Two or more microelectronic elements 602 and 604 (such as semiconductor elements, including, for example, integrated device dies, wafers, passive devices, individual active devices such as power switches, etc.) may be stacked on or bonded to one another to form the bonded structure 600. Conductive features 606a (e.g., contact pads, exposed ends of vias (e.g., TSVs), or a through substrate electrodes) of a first element 602 may be electrically connected to corresponding conductive features 606b of a second element 604. Any suitable number of elements can be stacked in the bonded structure 600. For example, a third element (not shown) can be stacked on the second element 604, a fourth element (not shown) can be stacked on the third element, and so forth. Additionally or alternatively, one or more additional elements (not shown) can be stacked laterally adjacent one another along the first element 602. In some implementations, the laterally stacked additional element may be smaller than the second element. In some implementations, the laterally stacked additional element may be two times smaller than the second element.

In some implementations, the elements 602 and 604 are directly bonded to one another without an intervening adhesive. In various implementations, a non-conductive field region that includes a non-conductive or dielectric material can serve as a first bonding layer 608a of the first element 602 which can be directly bonded to a corresponding non-conductive field region that includes a non-conductive or dielectric material serving as a second bonding layer 608b of the second element 604 without an intervening adhesive. The non-conductive bonding layers 608a and 608b can be disposed on respective front sides 614a and 614b of device portions 610a and 610b, such as a semiconductor (e.g., silicon) portion of the elements 602, 604. Active devices and/or circuitry can be patterned and/or otherwise disposed in or on the device portions 610a and 610b. Active devices and/or circuitry can be disposed at or near the front sides 614a and 614b of the device portions 610a and 610b, and/or at or near opposite backsides 616a and 616b of the device portions 610a and 610b. Bonding layers can be provided on front sides and/or back sides of the elements. The non-conductive material can be referred to as a non-conductive bonding region or bonding layer 608a of the first element 602. In some implementations, the non-conductive bonding layer 608a of the first element 602 can be directly bonded to the corresponding non-conductive bonding layer 608b of the second element 604 using dielectric-to-dielectric bonding techniques. For example, non-conductive or dielectric-to-dielectric bonds may be formed without an intervening adhesive using the direct bonding techniques disclosed at least in U.S. Pat. Nos. 9,664,414; 9,391,143; and 10,434,749, the entire contents of each of which are incorporated by reference herein in their entirety and for all purposes. It should be appreciated that in various implementations, the bonding layers 608a and/or 608b can comprise a non-conductive material such as a dielectric material, such as silicon oxide, or an undoped semiconductor material, such as undoped silicon. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some implementations, the dielectric materials do not comprise polymer materials, such as epoxy, resin or molding materials.

In some implementations, the device portions 610a and 610b can have a significantly different coefficients of thermal expansion (CTEs) defining a heterogenous structure. The CTE difference between the device portions 610a and 610b, and particularly between bulk semiconductor, typically single crystal portions of the device portions 610a, 610b, can be greater than 5 ppm or greater than 10 ppm. For example, the CTE difference between the device portions 610a and 610b can be in a range of 5 ppm to 100 ppm, 5 ppm to 40 ppm, 10 ppm to 100 ppm, or 10 ppm to 40 ppm. In some implementations, one of the device portions 610a and 610b can comprise optoelectronic single crystal materials, including perovskite materials, that are useful for optical piezoelectric or pyroelectric applications, and the other of the device portions 610a, 610b comprises a more conventional substrate material. For example, one of the device portions 610a, 610b comprises lithium tantalate (LiTaO3) or lithium niobate (LiNbO3), and the other one of the device portions 610a, 610b comprises silicon (Si), quartz, fused silica glass, sapphire, or a glass. In other implementations, one of the device portions 610a and 610b comprises a III-V single semiconductor material, such as gallium arsenide (GaAs) or gallium nitride (GaN), and the other one of the device portions 610a and 610b can comprise a non-III-V semiconductor material, such as silicon (Si), or can comprise other materials with similar CTE, such as quartz, fused silica glass, sapphire, or a glass.

In various implementations, direct hybrid bonds can be formed without an intervening adhesive. For example, nonconductive bonding surfaces 612a and 612b can be polished to a high degree of smoothness. The nonconductive bonding surfaces 612a and 612b can be polished using, for example, chemical mechanical polishing (CMP). The roughness of the polished bonding surfaces 612a and 612b can be less than 30 Å rms. For example, the roughness of the bonding surfaces 612a and 612b can be in a range of about 0.1 Å rms to 15 Å rms, 0.5 Å rms to 10 Å rms, or 1 Å rms to 5 Å rms. The bonding surfaces 612a and 612b can be cleaned and exposed to a plasma and/or etchants to activate the surfaces 612a and 612b. In some implementations, the surfaces 612a and 612b can be terminated with a species after activation or during activation (e.g., during the plasma and/or etch processes). Without being limited by theory, in some implementations, the activation process can be performed to break chemical bonds at the bonding surfaces 612a and 612b, and the termination process can provide additional chemical species at the bonding surfaces 612a and 612b that improves the bonding energy during direct bonding. In some implementations, the activation and termination are provided in the same step, e.g., a plasma to activate and terminate the surfaces 612a and 612b. In other implementations, the bonding surfaces 612a and 612b can be terminated in a separate treatment to provide the additional species for direct bonding. In various implementations, the terminating species can comprise nitrogen. For example, in some implementations, the bonding surface(s) 612a, 612b can be exposed to a nitrogen-containing plasma. Further, in some implementations, the bonding surfaces 612a and 612b can be exposed to fluorine. For example, there may be one or multiple fluorine peaks at or near a bond interface 618 between the first and second elements 602, 604. Thus, in the directly bonded structure 600, the bond interface 618 between two non-conductive materials (e.g., the bonding layers 608a and 608b) can comprise a very smooth interface with higher nitrogen content and/or fluorine peaks at the bond interface 618. Additional examples of activation and/or termination treatments may be found throughout U.S. Pat. Nos. 9,664,414; 9,391,143; and 10,434,749, the entire contents of each of which are incorporated by reference herein in their entirety and for all purposes. The roughness of the polished bonding surfaces 612a and 612b can be slightly rougher (e.g., about 1 Å rms to 30 Å rms, 3 Å rms to 20 Å rms, or possibly rougher) after an activation process.

In various implementations, conductive features 606a of the first element 602 can also be directly bonded to corresponding conductive features 606b of the second element 604. For example, a direct hybrid bonding technique can be used to provide conductor-to-conductor direct bonds along the bond interface 618 that includes covalently direct bonded non-conductive-to-non-conductive (e.g., dielectric-to-dielectric) surfaces, prepared as described above. In various implementations, the conductor-to-conductor (e.g., conductive feature 606a to conductive feature 606b) direct bonds and the dielectric-to-dielectric hybrid bonds can be formed using the direct bonding techniques disclosed at least in U.S. Pat. Nos. 9,716,033 and 9,652,988, the entire contents of each of which are incorporated by reference herein in their entirety and for all purposes. In direct hybrid bonding implementations described herein, conductive features are provided within non-conductive bonding layers, and both conductive and nonconductive features are prepared for direct bonding, such as by the planarization, activation and/or termination treatments described above. Thus, the bonding surface prepared for direct bonding includes both conductive and non-conductive features.

For example, non-conductive (e.g., dielectric) bonding surfaces 612a, 612b (e.g., inorganic dielectric surfaces) can be prepared and directly bonded to one another without an intervening adhesive as explained above. Conductive contact features (e.g., conductive features 606a and 606b which may be at least partially surrounded by non-conductive dielectric field regions within the bonding layers 608a, 608b) may also directly bond to one another without an intervening adhesive. In various implementations, the conductive features 606a, 606b can comprise discrete pads or traces at least partially embedded in the non-conductive field regions. In some implementations, the conductive contact features can comprise exposed contact surfaces of through substrate vias (e.g., through silicon vias (TSVs)). In some implementations, the respective conductive features 606a and 606b can be recessed below exterior (e.g., upper) surfaces (non-conductive bonding surfaces 612a and 612b) of the dielectric field region or non-conductive bonding layers 608a and 608b, for example, recessed by less than 30 nm, less than 20 nm, less than 15 nm, or less than 10 nm, for example, recessed in a range of 2 nm to 20 nm, or in a range of 4 nm to 10 nm. In various implementations, prior to direct bonding, the recesses in the opposing elements can be sized such that the total gap between opposing contact pads is less than 15 nm, or less than 10 nm. The non-conductive bonding layers 608a and 608b can be directly bonded to one another without an adhesive at room temperature in some implementations and, subsequently, the bonded structure 600 can be annealed. Upon annealing, the conductive features 606a and 606b can expand and contact one another to form a metal-to-metal direct bond. Beneficially, the use of Direct Bond Interconnect, or DBI®, techniques commercially available from Adeia of San Jose, CA, can enable high density of conductive features 606a and 606b to be connected across the direct bond interface 618 (e.g., small or fine pitches for regular arrays). In some implementations, the pitch of the conductive features 606a and 606b, such as conductive traces embedded in the bonding surface of one of the bonded elements, may be less than 100 microns or less than 10 microns or even less than 2 microns. For some applications, the ratio of the pitch of the conductive features 606a and 606b to one of the dimensions (e.g., a diameter) of the bonding pad is less than is less than 20, or less than 10, or less than 5, or less than 3 and sometimes desirably less than 2. In other applications, the width of the conductive traces embedded in the bonding surface of one of the bonded elements may range between 0.3 to 20 microns, e.g., in a range of 0.3 to 3 microns. In various implementations, the conductive features 606a and 606b and/or traces can comprise copper or copper alloys, although other metals may be suitable. For example, the conductive features disclosed herein, such as the conductive features 606a and 606b, can comprise fine-grain metal (e.g., a fine-grain copper).

Thus, in direct bonding processes, a first element 602 can be directly bonded to a second element 604 without an intervening adhesive. In some arrangements, the first element 602 can comprise a singulated element, such as a singulated integrated device die. In other arrangements, the first element 602 can comprise a carrier or substrate (e.g., a wafer) that includes a plurality (e.g., tens, hundreds, or more) of device regions that, when singulated, form a plurality of integrated device dies. Similarly, the second element 604 can comprise a singulated element, such as a singulated integrated device die. In other arrangements, the second element 604 can comprise a carrier or substrate (e.g., a wafer). The implementations disclosed herein can accordingly apply to wafer-to-wafer (W2W), die-to-die (D2D), or die-to-wafer (D2W) bonding processes. In wafer-to-wafer (W2W) processes, two or more wafers can be directly bonded to one another (e.g., direct hybrid bonded) and singulated using a suitable singulation process. After singulation, side edges of the singulated structure (e.g., the side edges of the two bonded elements) may be substantially flush and may include markings indicative of the common singulation process for the bonded structure (e.g., saw markings if a saw singulation process is used).

As explained herein, the first and second elements 602 and 604 can be directly bonded to one another without an adhesive, which is different from a deposition process and results in a structurally different interface compared to a deposition. In one application, a width of the first element 602 in the bonded structure is similar to a width of the second element 604. In some other implementations, a width of the first element 602 in the bonded structure 600 is different from a width of the second element 604. Similarly, the width or area of the larger element in the bonded structure may be at least 10% larger than the width or area of the smaller element. The first and second elements 602 and 604 can accordingly comprise non-deposited elements. Further, directly bonded structures 600, unlike deposited layers, can include a defect region along the bond interface 618 in which nanometer-scale voids (nanovoids) are present. The nanovoids may be formed due to activation of the bonding surfaces 612a and 612b (e.g., exposure to a plasma). As explained above, the bond interface 618 can include concentration of materials from the activation and/or last chemical treatment processes. For example, in implementations that utilize a nitrogen plasma for activation, a nitrogen peak can be formed at the bond interface 618. The nitrogen peak can be detectable using secondary ion mass spectroscopy (SIMS) techniques. In various implementations, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In implementations that utilize an oxygen plasma for activation, an oxygen peak can be formed at the bond interface 618. In some implementations, the bond interface 618 can comprise silicon oxynitride, silicon oxycarbonitride, or silicon carbonitride. As explained herein, the direct bond can comprise a covalent bond, which is stronger than van Der Waals bonds. The bonding layers 608a and 608b can also comprise polished surfaces that are planarized to a high degree of smoothness.

In various implementations, the metal-to-metal bonds between the conductive features 606a and 606b can be joined such that metal grains grow into each other across the bond interface 618. In some implementations, the metal is or includes copper, which can have grains oriented along the 611 crystal plane for improved copper diffusion across the bond interface 618. In some implementations, the conductive features 606a and 606b may include nanotwinned copper grain structure, which can aid in merging the conductive features during anneal. The bond interface 618 can extend substantially entirely to at least a portion of the bonded conductive features 606a and 606b, such that there is substantially no gap between the non-conductive bonding layers 608a and 608b at or near the bonded conductive features 606a and 606b. In some implementations, a barrier layer may be provided under and/or laterally surrounding the conductive features 606a and 606b (e.g., which may include copper). In other implementations, however, there may be no barrier layer under the conductive features 606a and 606b, for example, as described in U.S. Pat. No. 11,195,748, which is incorporated by reference herein in its entirety and for all purposes.

Beneficially, the use of the hybrid bonding techniques described herein can enable extremely fine pitch between adjacent conductive features 606a and 606b, and/or small pad sizes. For example, in various implementations, the pitch p (e.g., the distance from edge-to-edge or center-to-center, as shown in FIG. 6A) between adjacent conductive features 606a (or 606b) can be in a range of 0.5 microns to 50 microns, in a range of 0.75 microns to 25 microns, in a range of 1 micron to 25 microns, in a range of 1 micron to 10 microns, or in a range of 1 micron to 5 microns. Further, a major lateral dimension (e.g., a pad diameter) can be small as well, e.g., in a range of 0.25 microns to 30 microns, in a range of 0.25 microns to 5 microns, or in a range of 0.5 microns to 5 microns.

As described above, the non-conductive bonding layers 608a, 608b can be directly bonded to one another without an adhesive and, subsequently, the bonded structure 600 can be annealed. Upon annealing, the conductive features 606a, 606b can expand and contact one another to form a metal-to-metal direct bond. In some implementations, the materials of the conductive features 606a, 606b can interdiffuse during the annealing process.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

Several illustrative examples of testing elements for bonded structures and related systems and methods have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps may be arranged or performed differently than described and components, elements, features, acts, or steps may be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed invention. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages and features of the inventions have been described herein. Not all, or any such advantages are necessarily achieved in accordance with any particular example of the inventions disclosed herein. No aspects of this disclosure are essential or indispensable. In many examples, the devices, systems, and methods may be configured differently than illustrated in the figures. or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

What is claimed is:

1. A bonded structure comprising:
a carrier comprising a nonconductive layer;
a first die coupled to the carrier, wherein the first die communicates according to a first communication protocol;
a second die coupled to the carrier, wherein the second die communicates according to a second communication protocol different from the first communication protocol; and
protocol switch circuitry at least partially embedded within the carrier, wherein, during operation of the bonded structure, the protocol switch circuitry receives a communication signal from the first die according to the first communication protocol, converts the communication signal to a converted communication signal according to the second communication protocol, and provides the converted communication signal to the second die.

2. The bonded structure of claim 1, wherein the carrier comprises a package substrate, an interposer, or a semiconductor element.

3. The bonded structure of claim 1, wherein material of the carrier laterally surrounds at least a portion of the protocol switch circuitry.

4. The bonded structure of claim 1, wherein the protocol switch circuitry comprises active circuitry of a die embedded within the carrier.

5. The bonded structure of claim 1, wherein at least one of the first die or the second die is directly bonded to the carrier without an intervening adhesive.

6. The bonded structure of claim 1, wherein the protocol switch circuitry converts a further communication signal from the second communication protocol to the first communication protocol.

7. The bonded structure of claim 1, further comprising a plurality of additional dies coupled to the carrier, wherein the protocol switch circuitry converts communication signals among more than two communication protocols used by the first die, the second die, and the plurality of additional dies.

8. The bonded structure of claim 1, wherein the protocol switch circuitry comprises a multiplexer that receives a selected protocol of a plurality of incoming communication protocols and provides the selected protocol for conversion to an outgoing communication protocol based at least on a control input.

9. A bonded structure comprising:
a carrier;
a first die disposed over the carrier, wherein the first die transmits a communication signal according to a first communication protocol;
a second die disposed over the carrier, wherein the second die receives the communication signal according to a second communication protocol different from the first communication protocol;
a protocol switch component disposed at least partially within the carrier, wherein, during operation of the bonded structure, the protocol switch component receives the communication signal from the first die, converts the communication signal from the first communication protocol to the second communication protocol, and transmits the communication signal to the second die; and
an encapsulating material disposed over at least a portion of the carrier and over at least one of the first die or the second die.

10. The bonded structure of claim 9, wherein carrier material of the carrier laterally surrounds at least a portion of the protocol switch component.

11. The bonded structure of claim 9, wherein the protocol switch component comprises a protocol switch die.

12. The bonded structure of claim 9, wherein the protocol switch component comprises protocol switch circuitry embedded within a nonconductive layer of the carrier.

13. The bonded structure of claim 9, wherein at least one of the first die or the second die is directly bonded to the carrier without an intervening adhesive.

14. The bonded structure of claim 9, wherein the encapsulating material is disposed over at least a portion of the protocol switch component.

15. An integrated device die comprising:
an input terminal that receives a signal formatted according to a first communication protocol;
protocol switching circuitry that, during operation of the integrated device die, converts the signal from the first communication protocol to a second communication protocol different from the first communication protocol; and
an output terminal that transmits the signal formatted according to the second communication protocol.

16. The integrated device die of claim 15, wherein the integrated device die is directly bonded to an element without an intervening adhesive.

17. The integrated device die of claim 16, wherein the integrated device die is hybrid bonded to the element.

18. The integrated device die of claim 15, further comprising a memory that stores communication protocols used by the protocol switching circuitry.

19. The integrated device die of claim 15, wherein a format of the first communication protocol and a format of the second communication protocol are based on at least one of architecture, data rate, a number of input/output interconnects, voltages, clock speed, power, latency, bit error rate, or channel loss.

20. The integrated device die of claim 15, further comprising a multiplexer that receives at least one protocol of a plurality of incoming communication protocols and provides the at least one protocol to the protocol switching circuitry for conversion to at least one protocol of a plurality of outgoing communication protocols based at least on a control input.
